(19) United States
(12) Patent Application Publication
(10) Pub. No.: US 2026/0363039 A1
(43) Pub. Date: Nov. 12, 2026

(54) METHOD FOR PREPARING SEMICONDUCTOR DEVICE STRUCTURE WITH THROUGH-SUBSTRATE VIA

(71) Applicant: NANYA TECHNOLOGY CORPORATION, NEW TAIPEI CITY (TW)

(72) Inventor: YI-LONG WONG, NEW TAIPEI CITY (TW)

(21) Appl. No.: 19/243,561

(22) Filed: Jun. 19, 2025

Related U.S. Application Data
(63) Continuation of application No. 19/199,606, filed on May 6, 2025.

(51) Int. Cl. H10W 20/00

(52) U.S. Cl. CPC H10W 20/023; H10W 20/032; H10W 20/056

(57) ABSTRACT

A method for preparing a semiconductor device structure includes forming an opening penetrating through a semiconductor substrate, and forming a barrier layer lining the opening. The method also includes forming a conductive layer in the opening and over the barrier layer and the semiconductor substrate. The method further includes implanting a dopant into the conductive layer during the forming of the conductive layer. In addition, the method includes annealing the conductive layer after the implanting the dopant, and planarizing the conductive layer and the barrier layer after the annealing.

### CROSS-REFERENCE TO RELATED APPLICATION

This application is a continuation application of U.S. Non-Provisional application Ser. No. 19/199,606 filed May 6, 2025, which is incorporated herein by reference in its entirety.

### TECHNICAL FIELD

The present disclosure relates to a method for preparing a semiconductor device structure, and more particularly, to a method for preparing a semiconductor device structure with a through-substrate via.

### DISCUSSION OF THE BACKGROUND

Semiconductor devices are essential for many modern applications. With the advancement of electronic technology, semiconductor devices are becoming smaller in size while providing greater functionality and including greater amounts of integrated circuitry. Due to the miniaturized scale of semiconductor devices, various types and dimensions of semiconductor devices providing different functionalities are integrated and packaged into a single module. Furthermore, numerous manufacturing operations are implemented for integration of various types of semiconductor devices.

However, the manufacturing and integration of semiconductor devices involve many complicated steps and operations. Integration in semiconductor devices becomes increasingly complicated. An increase in complexity of manufacturing and integration of the semiconductor devices may cause deficiencies. Accordingly, there is a continuous need to improve the manufacturing process of semiconductor devices so that the problems can be addressed.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

In one embodiment of the present disclosure, a method for preparing a semiconductor device structure is provided. The method includes forming an opening penetrating through a semiconductor substrate, and forming a barrier layer lining the opening. The method also includes forming a conductive layer in the opening and over the barrier layer and the semiconductor substrate. The method further includes implanting a dopant into the conductive layer during the forming of the conductive layer. In addition, the method includes annealing the conductive layer after the implanting the dopant, and planarizing the conductive layer and the barrier layer after the annealing.

In an embodiment, the dopant includes nitrogen (N). In an embodiment, the conductive layer has a protruding portion overlapping the opening before the annealing is performed, and the dopant is implanted into the protruding portion of the conductive layer. In an embodiment, the dopant is implanted into the conductive layer and the barrier layer during the forming of the conductive layer. In an embodiment, the implanting is performed at an energy of between about 1 KeV and about 3 KeV. In an embodiment, the implanting uses an implantation dosage between about 3×10⁶ atoms/cm² and about 6×10⁶ atoms/cm².

In an embodiment, the annealing is performed at a temperature of between about 350 °C and about 420 °C. In an embodiment, the conductive layer is formed by a plating process, and the conductive layer includes copper (Cu). In an embodiment, a thickness of the conductive layer over a top surface of the semiconductor substrate is in a range from about 0.5 μm to about 2 μm. In an embodiment, the barrier layer extends over the semiconductor substrate before the conductive layer is formed.

In an embodiment, a thickness of the barrier layer over a top surface of the semiconductor substrate is in a range from about 50 nm to about 100 nm. In an embodiment, the method further includes forming an isolation layer lining the opening and over the semiconductor substrate before the barrier layer is formed. In an embodiment, a portion of the isolation layer over the semiconductor substrate is removed by the planarizing. In an embodiment, after the planarizing, a top surface of the conductive layer is slightly concave, while a top surface of the barrier layer is substantially coplanar with a top surface of the isolation layer.

In another embodiment of the present disclosure, a method for preparing a semiconductor device structure is provided. The method includes forming an opening penetrating through a semiconductor substrate, and forming a barrier layer lining the opening and over a top surface of the semiconductor substrate. The method also includes forming a conductive layer in the opening and simultaneously implanting a dopant in the conductive layer. The method further includes annealing the conductive layer. In addition, the method includes planarizing the conductive layer and the barrier layer after the annealing. A top surface of the conductive layer is slightly concave while a top surface of the barrier layer is substantially planar after the planarizing.

In an embodiment, the dopant includes nitrogen (N). In an embodiment, the conductive layer includes copper (Cu), and the barrier layer includes tantalum (Ta). In an embodiment, the implanting is performed at an energy of between about 1 KeV and about 3 KeV. In an embodiment, the implanting uses an implantation dosage between about 3×10⁶ atoms/cm² and about 6×10⁶ atoms/cm². In an embodiment, the conductive layer has a protruding portion overlapping the opening before the annealing is performed. In an embodiment, the conductive layer has an extending portion extending over the top surface of the semiconductor substrate, and the protruding portion of the conductive layer protrudes from a top surface of the extending portion of the conductive layer.

In an embodiment, the protruding portion of the conductive layer has a first height over the top surface of the extending portion of the conductive layer before the annealing, and the protruding portion of the conductive layer has a second height over the top surface of the extending portion of the conductive layer after the annealing, and wherein the second height is greater than the first height. In an embodiment, the dopant is implanted into the protruding portion and the extending portion of the conductive layer. In an embodiment, the dopant is implanted into the barrier layer.

In an embodiment, the method further includes forming a dielectric layer over the semiconductor substrate before the opening is formed, and forming the opening penetrating through the semiconductor substrate and the dielectric layer. In addition, the method includes forming an isolation layer lining the opening and over the dielectric layer before the barrier layer is formed. In an embodiment, the planarizing the conductive layer and the barrier layer further includes performing a first planarization process to expose the isolation layer, and performing a second planarization process to expose the dielectric layer. In an embodiment, the conductive layer and the barrier layer have substantially coplanar top surfaces after the first planarization process and before the second planarization process.

In yet another embodiment of the present disclosure, a method for preparing a semiconductor device structure is provided. The method includes forming a conductive pad over a first side of a semiconductor substrate, and forming a dielectric layer over a second side of the semiconductor substrate. The second side is opposite to the first side. The method also includes etching the dielectric layer and the semiconductor substrate to form an opening partially exposing the conductive pad, and forming an isolation layer lining the opening and over the dielectric layer. The method further includes forming a barrier layer lining the opening and over the isolation layer, and forming a conductive layer in the opening and implanting a dopant into the conductive layer during the forming of the conductive layer. The barrier layer is sandwiched between the conductive layer and the isolation layer. In addition, the method includes annealing the conductive layer after the implanting, and planarizing the conductive layer and the barrier layer after the annealing.

In an embodiment, the conductive layer comprises copper (Cu), and the dopant comprises nitrogen (N). In an embodiment, the implanting the dopant into the conductive layer is performed at an energy of between about 1 KeV and about 3 KeV. In an embodiment, the implanting the dopant into the conductive layer uses an implantation dosage between about 3×10⁶ atoms/cm² and about 6×10⁶ atoms/cm². In an embodiment, the dielectric layer and the isolation layer comprise different materials.

In an embodiment, the isolation layer is formed lining the opening and covering the conductive pad. In an embodiment, the method further includes etching the isolation layer to partially expose the conductive pad before the barrier layer is formed. In an embodiment, a first doped region is formed in the conductive layer by the implanting, and a bottom surface of the first doped region is higher than or substantially level with a top surface of the isolation layer. In an embodiment, a second doped region is formed in the barrier layer by the implanting, and a bottom surface of the second doped region is higher than or substantially level with the top surface of the isolation layer.

In an embodiment, the planarizing the conductive layer and the barrier layer further includes performing a first planarization process to expose the isolation layer, and performing a second planarization process to expose the dielectric layer. In an embodiment, a top surface of the conductive layer is slightly concave after the second planarization process is performed. In an embodiment, a top surface of the barrier layer is substantially coplanar with a top surface of the isolation layer after the second planarization process is performed. In an embodiment, the top surface of the barrier layer is substantially coplanar with a top surface of the dielectric layer after the second planarization process is performed.

Embodiments of a method for preparing a semiconductor device structure are provided in the disclosure. The method includes forming an opening penetrating through a semiconductor substrate, forming a barrier layer lining the opening, and forming a conductive layer in the opening. The conductive layer is formed over the barrier layer. The method also includes implanting a dopant into the conductive layer during the forming of the conductive layer. The method further includes annealing the conductive layer and planarizing the conductive layer and the barrier layer to form a through-substrate via (TSV). As a result, a top surface of the conductive layer of the TSV is slightly concave or substantially planar while a top surface of the barrier layer of the TSV is substantially planar, thereby improving the overall performance of the semiconductor device structure.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flow diagram illustrating a method for preparing a semiconductor device structure, in accordance with some embodiments.

FIG. 2 is a cross-sectional view illustrating an intermediate stage of forming a conductive pad and a first dielectric layer over a first side of a semiconductor substrate during the preparation of the semiconductor device structure, in accordance with some embodiments.

FIG. 3 is a cross-sectional view illustrating an intermediate stage of sequentially forming a second dielectric layer and a third dielectric layer over a second side of the semiconductor substrate during the preparation of the semiconductor device structure, in accordance with some embodiments.

FIG. 4 is a cross-sectional view illustrating an intermediate stage of etching the third dielectric layer, the second dielectric layer and the semiconductor substrate to form an opening exposing the conductive pad during the preparation of the semiconductor device structure, in accordance with some embodiments.

FIG. 5 is a cross-sectional view illustrating an intermediate stage of forming an isolation layer lining the opening and over the third dielectric layer during the preparation of the semiconductor device structure, in accordance with some embodiments.

FIG. 6 is a cross-sectional view illustrating an intermediate stage of forming a patterned mask over the isolation layer during the preparation of the semiconductor device structure, in accordance with some embodiments.

FIG. 7 is a cross-sectional view illustrating an intermediate stage of etching the isolation layer to partially expose the conductive pad during the preparation of the semiconductor device structure, in accordance with some embodiments.

FIG. 8 is a cross-sectional view illustrating an intermediate stage of forming a barrier layer lining the opening and over the isolation layer during the preparation of the semiconductor device structure, in accordance with some embodiments.

FIG. 9 is a cross-sectional view illustrating an intermediate stage of forming a conductive layer in the opening and implanting a dopant into the conductive layer during the preparation of the semiconductor device structure, in accordance with some embodiments.

FIG. 10 is a cross-sectional view illustrating a dopant distribution after implanting the dopant during the preparation of the semiconductor device structure, in accordance with some embodiments.

FIG. 11 is a cross-sectional view illustrating an intermediate stage of annealing the conductive layer during the preparation of the semiconductor device structure, in accordance with some embodiments.

FIG. 12 is a cross-sectional view illustrating an intermediate stage of performing a first planarization process during the preparation of the semiconductor device structure, in accordance with some embodiments.

FIG. 13 is a cross-sectional view illustrating an intermediate stage of performing a second planarization process during the preparation of the semiconductor device structure, in accordance with some embodiments.

FIG. 14 is a cross-sectional view illustrating an intermediate stage of forming a patterned mask over the barrier layer during the preparation of the semiconductor device structure, in accordance with some other embodiments.

FIG. 15 is a cross-sectional view illustrating an intermediate stage of etching the barrier layer to partially expose the conductive pad during the preparation of the semiconductor device structure, in accordance with some other embodiments.

FIG. 16 is a cross-sectional view illustrating an intermediate stage of forming a conductive layer in the opening and implanting a dopant into the conductive layer during the preparation of the semiconductor device structure, in accordance with some other embodiments.

FIG. 17 is a cross-sectional view illustrating an intermediate stage of sequentially performing a first planarization process and a second planarization process during the preparation of the semiconductor device structure, in accordance with some other embodiments.

FIG. 18 is a cross-sectional view illustrating a dopant distribution after implanting the dopant during the preparation of the semiconductor device structure, in accordance with some other embodiments.

FIG. 19 is a cross-sectional view illustrating a dopant distribution after implanting the dopant during the preparation of the semiconductor device structure, in accordance with some other embodiments.

FIG. 20 is a cross-sectional view illustrating a dopant distribution after implanting the dopant during the preparation of the semiconductor device structure, in accordance with some other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

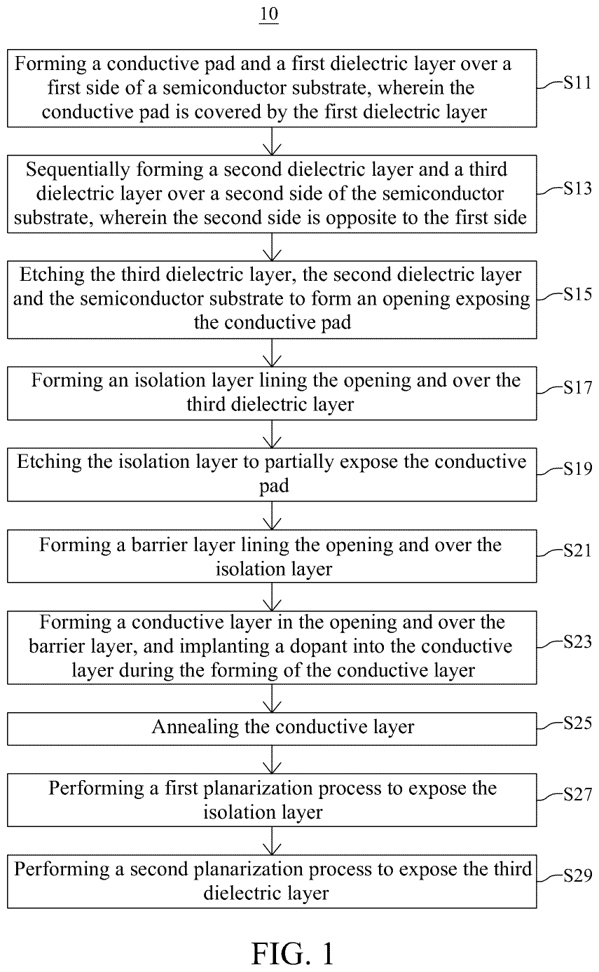

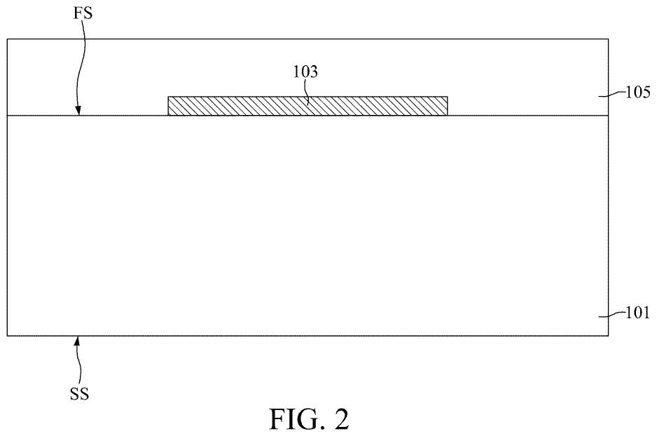

FIG. 1 is a flow diagram illustrating a method 10 for preparing a semiconductor device structure, and the method 10 includes steps S11, S13, S15, S17, S19, S21, S23, S25, S27 and S29, in accordance with some embodiments. The steps S11-S29 of FIG. 1 are first introduced briefly and then elaborated in connection with FIGS. 2-20. As shown in FIG. 1, the method 10 begins at step S11 where a conductive pad and a first dielectric layer are formed over a first side of a semiconductor substrate. In some embodiments, the conductive pad is covered by the first dielectric layer.

Next, as step S13, a second dielectric layer and a third dielectric layer are sequentially formed over a second side of the semiconductor substrate. The second side of the semiconductor substrate is opposite to the first side of the semiconductor substrate. In some embodiments, the semiconductor substrate is flipped over so that the second side faces upward during the formation of the second dielectric layer and the third dielectric layer.

At step S15, the third dielectric layer, the second dielectric layer and the semiconductor substrate are etched to form an opening exposing the conductive pad. In some embodiments, the opening penetrates through the third dielectric layer, the second dielectric layer and the semiconductor substrate. At step S17, an isolation layer is formed lining the opening and over the third dielectric layer. In some embodiments, the isolation layer is conformally deposited and extends outside the opening to cover the third dielectric layer. In some embodiments, the conductive pad is covered by the isolation layer.

Subsequently, at step S19, the isolation layer is etched to partially expose the conductive pad. At step S21, a barrier layer is formed lining the opening and over the isolation layer. In some embodiments, the barrier layer is conformally deposited and extends outside the opening to cover the isolation layer. In some embodiments, the conductive pad is covered by and in direct contact with the barrier layer.

At step S23, a conductive layer is formed in the opening and over the barrier layer, and implanting a dopant into the conductive layer during the forming of the conductive layer. In some embodiments, the formation of the conductive layer and the implantation of the dopant are performed simultaneously. At step S25, an annealing process is performed on the conductive layer.

Then, at step S27, a first planarization process is performed to remove a portion of the conductive layer and a portion of the barrier layer, thereby exposing the isolation layer. In some embodiments, the conductive layer, the barrier layer, and the isolation layer have substantially coplanar top surfaces after the first planarization process is performed. Next, at step S29, a second planarization process is performed to remove a portion of the isolation layer, a portion of the barrier layer, and a portion of the conductive layer, thereby exposing the third dielectric layer. After the step S29, a semiconductor device structure with a through-substrate via (TSV) is obtained.

In some embodiments, a top surface of the conductive layer is slightly concave or substantially planar after the second planarization process. In some embodiments, a recess is formed over the conductive layer by the second planarization process, such that the top surface of the conductive layer is slightly concave, while a top surface of the barrier layer is substantially planar. In some embodiments, the barrier layer, the isolation layer and the third dielectric layer have substantially coplanar top surfaces after the second planarization process is performed. In some other embodiments, the top surface of the conductive layer is substantially coplanar with the top surface of the barrier layer and the top surface of the isolation layer after the second planarization process is performed (i.e., the recess over the conductive layer does not exists).

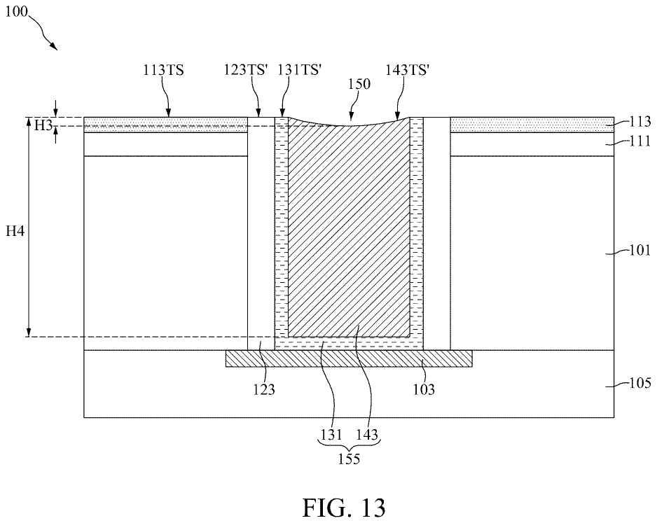

FIGS. 2-13 are cross-sectional views illustrating various stages of forming the semiconductor device structure 100 (FIG. 13) by the method 10 of FIG. 1, in accordance with some embodiments. As shown in FIG. 2, a conductive pad 103 and a first dielectric layer 105 are formed over a first side FS of a semiconductor substrate 101, in accordance with some embodiments. The respective step is illustrated as the step S11 in the method 10 shown in FIG. 1. The semiconductor substrate 101 may be or may include a package substrate, an interposer, a printed circuit board (PCB), and/or other circuit carrier that is capable of carrying integrated circuits (IC).

The semiconductor substrate 101 may include various passive and active microelectronic devices, such as resistors, capacitors, inductors, diodes, p-type field effect transistors (pFETs), n-type field effect transistors (nFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, fin field-effect transistors (FinFETs), other suitable integrated circuit (IC) components, or combinations thereof.

Moreover, the semiconductor substrate 101 may include various material layers (e.g., dielectric layers, semiconductor layers, and/or conductive layers) configured to form IC features (e.g., doped regions, isolation features, gate features, source/drain features, interconnect features, other features, or combinations thereof). The semiconductor substrate 101 has been simplified for the sake of clarity. It should be noted that additional features can be added in the semiconductor substrate 101, and some of the features described below can be replaced, modified, or eliminated in other embodiments.

Still referring to FIG. 2, the conductive pad 103 is formed

over the first side FS of the semiconductor substrate 101, in accordance with some embodiments. In some embodiments, the conductive pad 103 includes aluminum (Al), copper (Cu), tungsten (W), titanium (Ti), tantalum (Ta), a combination thereof, or another suitable conductive material. The formation of the conductive pad 103 may include a deposition process and a subsequent etching process. The deposition process may include a chemical vapor deposition (CVD) process, a physical vapor deposition (PVD) process, an atomic layer deposition (ALD) process, a spin-on coating process, or another suitable deposition processes. The etching process may include a wet etching process, a dry etching process, or a combination thereof.

In some embodiments, the dielectric layer 105 is formed over the first side FS of the semiconductor substrate 101, and the conductive pad 103 is covered by the dielectric layer 105. In some embodiments, the dielectric layer 105 includes silicon oxide, silicon nitride, silicon oxynitride, tetraethylorthosilicate (TEOS) formed oxide, undoped silicate glass, doped silicon oxide (e.g., phosphosilicate glass (PSG), borophosphosilicate glass (BPSG), boron doped silicon glass (BSG)), a low-k dielectric material, a combination thereof, or another suitable dielectric material. The dielectric layer 105 may be formed by a deposition process, such as a CVD process, a PVD process, an ALD process, a spin-on coating process, or another suitable deposition process.

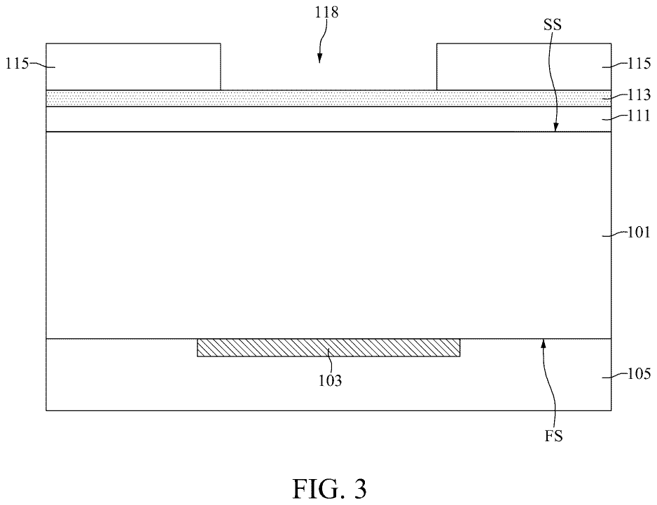

Next, the structure shown in FIG. 2 is flipped upside down so that a second side SS of the semiconductor substrate 101 faces upward, in accordance with some embodiments. In some embodiments, the second side SS of the semiconductor substrate 101 is opposite to the first side FS of the semiconductor substrate 101. In some embodiments, a second dielectric layer 111 and a third dielectric layer 113 are sequentially formed over the second side SS of the semiconductor substrate 101, as shown in FIG. 3 in accordance with some embodiments. The respective step is illustrated as the step S13 in the method 10 shown in FIG. 1.

In some embodiments, the second dielectric layer 111 includes silicon oxide. However, other materials, such as silicon nitride and silicon oxynitride, may also be used for the second dielectric layer 111. In some embodiments, the second dielectric layer 111 is formed by a deposition process, such as a CVD process, a PVD process, an ALD process, a spin-on coating process, or another suitable deposition process.

In addition, the third dielectric layer 113 includes silicon nitride. However, other materials, such as silicon oxide and silicon oxynitride, may also be used for the third dielectric layer 113. In some embodiments, a material of the second dielectric layer 111 is different from a material of the third dielectric layer 113. In some embodiments, the second dielectric layer 111 is formed by a deposition process, such as a CVD process, a PVD process, an ALD process, a spin-on coating process, or another suitable deposition process.

After the second dielectric layer 113 is formed, a patterned mask 115 is formed over the third dielectric layer 113, as shown in FIG. 3 in accordance with some embodiments. In some embodiments, the third dielectric layer 113 is partially exposed by an opening 118 penetrating through the patterned mask 115. In some embodiments, the patterned mask 115 is formed over the second side SS of the semiconductor substrate 101.

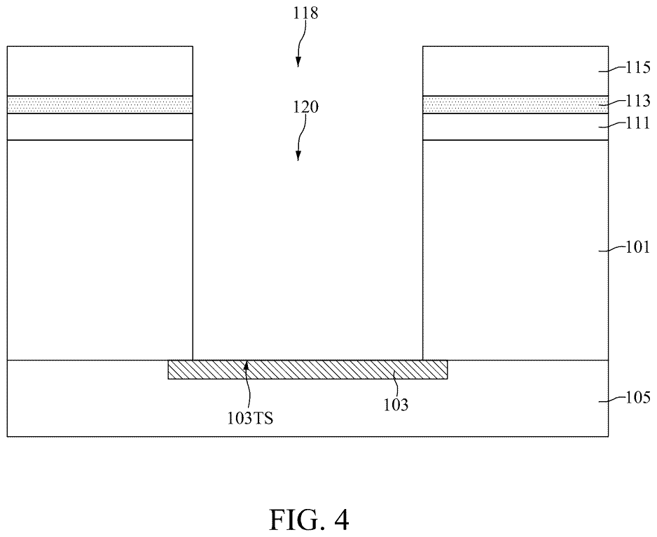

Subsequently, the third dielectric layer 113, the second dielectric layer 111 and the semiconductor substrate 101 are etched using the patterned mask 115 as an etching mask to form an opening 120, as shown in FIG. 4 in accordance with some embodiments. In other words, the opening 118 of the patterned mask 115 is transferred to the underlying layers. The respective step is illustrated as the step S15 in the method 10 shown in FIG. 1.

In some embodiments, the opening 120 penetrates through the third dielectric layer 113, the second dielectric layer 111 and the semiconductor substrate 101. In some embodiments, the top surface 103TS of the conductive pad 103 is partially exposed by the opening 120. In some embodiments, the opening 120 is formed by a dry etching process, a wet etching process, or a combination thereof. After the opening 120 is formed, the patterned mask 115 may be removed. In some embodiments, the patterned mask 115 is removed by a stripping process, an ashing process, an etching process, or another suitable process.

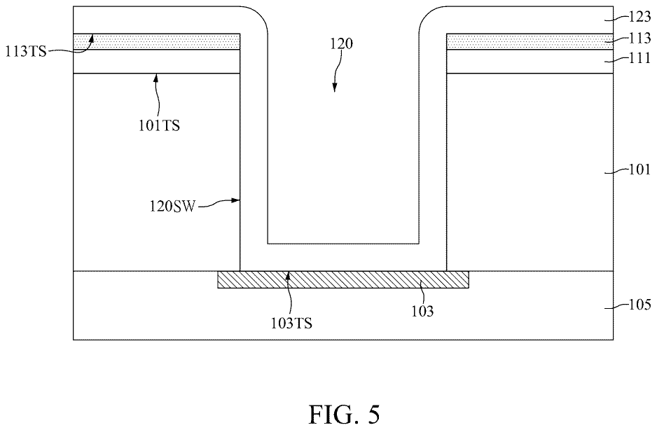

Then, an isolation layer 123 is formed lining the opening 120 and over the third dielectric layer 113, as shown in FIG. 5 in accordance with some embodiments. The respective step is illustrated as the step S17 in the method 10 shown in FIG. 1. In some embodiments, the isolation layer 123 is conformally deposited over the structure shown in FIG. 4.

In some embodiments, the isolation layer 123 extends over the top surface 101TS of the semiconductor substrate 101. In some embodiments, the top surface 103TS of the conductive pad 103 is covered by and in direct contact with the isolation layer 123. In some embodiments, the top surface 113TS of the third dielectric layer 113, the sidewall 120SW of the opening 120, and the bottom surface of the opening 120 (i.e., the exposed portion of the top surface 103TS of the conductive pad 103) are covered by and in direct contact with the isolation layer 123.

Moreover, in some embodiments, the isolation layer 123 includes silicon oxide. However, other materials, such as silicon nitride and silicon oxynitride, may also be used for the isolation layer 123. In some embodiments, a material of the isolation layer 123 is different from a material of the third dielectric layer 113. In some embodiments, the isolation layer 123 is formed by a deposition process, such as a CVD process, a PVD process, an ALD process, a spin-on coating process, or another suitable deposition process.

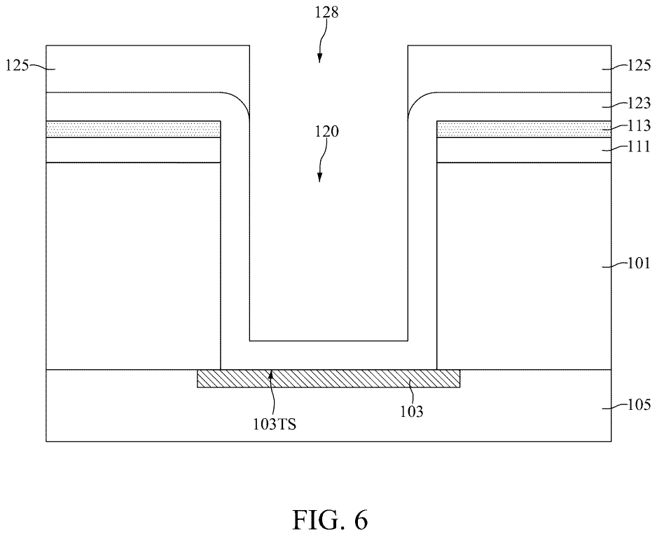

Next, a patterned mask 125 is formed over the isolation layer 123, as shown in FIG. 6 in accordance with some embodiments. In some embodiments, a portion of the isolation layer 123 that is in direct contact with the conductive pad 103 is exposed by an opening 128 in the patterned mask 125. In some embodiments, the opening 128 overlaps the opening 120 (see FIG. 4). In some embodiments, the opening 128 is entirely located in the opening 120 from a top view.

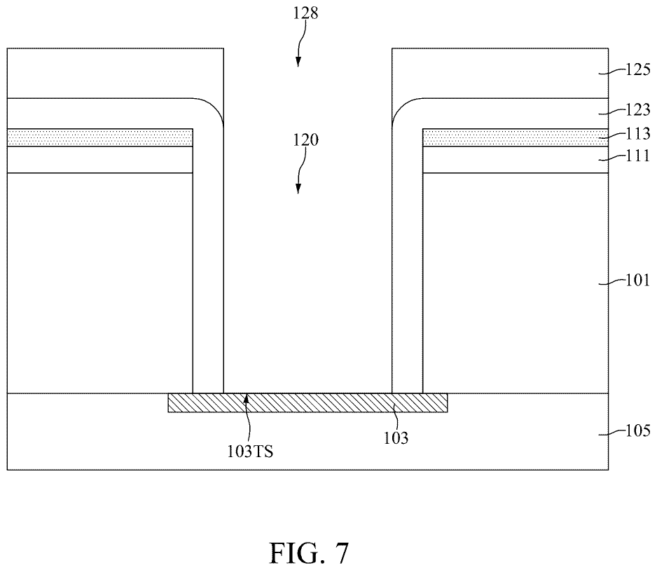

Subsequently, the isolation layer 123 is etched using the patterned mask 125 as an etching mask to partially expose the conductive pad 103, as shown in FIG. 7 in accordance with some embodiments. The respective step is illustrated as the step S19 in the method 10 shown in FIG. 1. In some embodiments, the top surface 103TS of the conductive pad 103 is partially exposed after the isolation layer 123 is etched.

In some embodiments, the isolation layer 123 is etched by a dry etching process, a wet etching process, or a combination thereof. After the top surface 103TS of the conductive pad 103 is partially exposed, the patterned mask 125 may be removed. In some embodiments, the patterned mask 125 is removed by a stripping process, an ashing process, an etching process, or another suitable process.

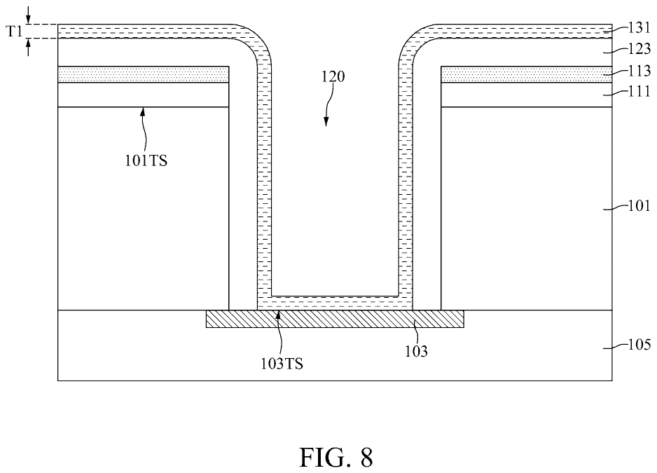

Then, a barrier layer 131 is formed lining the opening 120 and over the isolation layer 123, as shown in FIG. 8 in accordance with some embodiments. The respective step is illustrated as the step S21 in the method 10 shown in FIG. 1. In some embodiments, the barrier layer 131 is conformally deposited over the structure shown in FIG. 7.

In some embodiments, the barrier layer 131 extends over the top surface 101TS of the semiconductor substrate 101. In some embodiments, the top surface 103TS of the conductive pad 103 is covered by and in direct contact with the barrier layer 131. In some embodiments, the barrier layer 131 includes tantalum (Ta). However, other materials, such as tantalum nitride (TaN), titanium (Ti), titanium nitride (TiN), may also be used for the barrier layer 131. Some processes used to form the barrier layer 131 are similar to, or the same as those used to form the isolation layer 123, and details thereof are not repeated herein. In some embodiments, the barrier layer 131 has a thickness T1, and the thickness T1 is in a range from about 50 nm to about 100 nm.

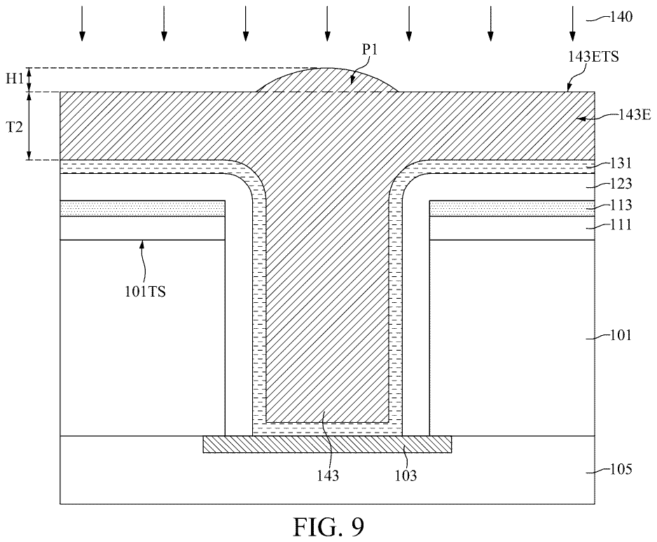

Next, a conductive layer 143 is formed in the opening 120 and over the barrier layer 131, and an implantation process 140 is performed to implant a dopant into the conductive layer 143, as shown in FIG. 9 in accordance with some embodiments. In some embodiments, the implantation process 140 is performed during the forming of the conductive layer 143. In some embodiments, the implantation process 140 and the forming of the conductive layer 143 are performed simultaneously. The respective step is illustrated as the step S23 in the method 10 shown in FIG. 1.

In some embodiments, after the barrier layer 131 is formed, a remaining portion of the opening 120 is filled with the conductive layer 143, and the conductive layer 143 extends over the top surface 101TS of the semiconductor substrate 101. In some embodiments, the conductive layer 143 has an extending portion 143E that extends over the top surface 101TS of the semiconductor substrate 101. In some embodiments, the conductive layer 143 has a protruding portion P1 overlapping the opening 120 (see FIG. 4). In some embodiments, the protruding portion P1 of the conductive layer 143 protrudes from the top surface 143ETS of the extending portion 143E of the conductive layer 143.

It is noted that the dashed line indicating the location of the protruding portion P1 is used to clarify the disclosure. No obvious interface exists within the conductive layer 143. In some embodiments, the conductive layer 143 includes copper (Cu). However, other materials, such as tungsten (W) or aluminum (Al), may also be used for the conductive layer 143. In some embodiments, the conductive layer 143 is formed by a plating process. In some embodiments, the extending portion 143E of the conductive layer 143 has a thickness T2, and the thickness T2 is in a range from about 0.5 μm to about 2 μm. In some embodiments, the protruding portion P1 of the conductive layer 143 has a height H1.

Moreover, in some embodiments, the dopant used in the implantation process 140 includes nitrogen (N). In some embodiments, the implantation process 140 is performed at an energy of between about 1 KeV and about 3 KeV. In some embodiments, the implantation process 140 uses an implantation dosage between about 3×10⁶ atoms/cm² and about 6×10⁶ atoms/cm². Since the implantation process 140 is performed during the formation of the conductive layer 143, the process cost can be reduced. Moreover, because the conductive layer 143 is doped with a dopant, such as nitrogen (N), the conductive layer 143 can exhibit a substantially planar or slightly concave top surface after the subsequent planarization process(es).

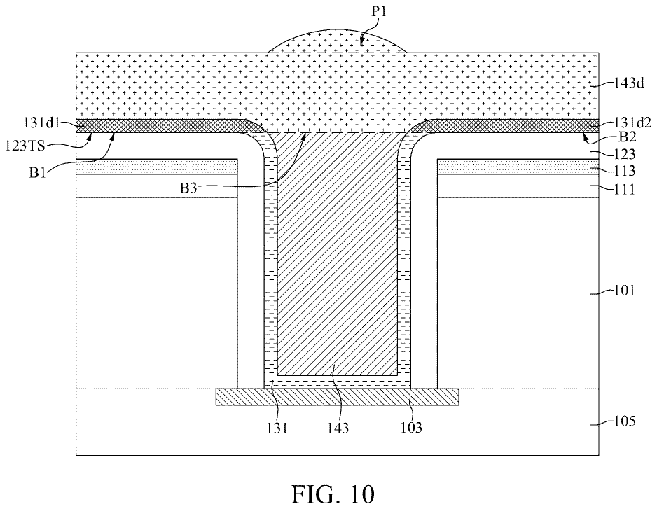

FIG. 10 is a cross-sectional view illustrating a dopant distribution after the implantation process 140 during the preparation of the semiconductor device structure 100, in accordance with some embodiments. As shown in FIG. 10, a doped region 143d is formed in the conductive layer 143, and doped regions 131d1 and 131d2 are formed in the barrier layer 131, in accordance with some embodiments. In some embodiments, the protruding portion P1 of the conductive layer 143 is located entirely within the doped region 143d. In some embodiments, the remaining portion of the conductive layer 143 and the remaining portion of the barrier layer 131 are undoped.

In the present embodiment, the bottom surface B1 of the doped region 131d1, the bottom surface B2 of the doped region 131d2, and the bottom surface B3 of the doped region 143d are substantially level with the top surface 123TS of the isolation layer 123. In some other embodiments, the bottom surface B1 of the doped region 131d1, the bottom surface B2 of the doped region 131d2, and the bottom surface B3 of the doped region 143d are higher than the top surface 123TS of the isolation layer 123. It is noted that the dashed line indicating the boundaries between the doped regions and the undoped regions are used to clarify the disclosure. No obvious interfaces exist between the doped regions and the undoped regions.

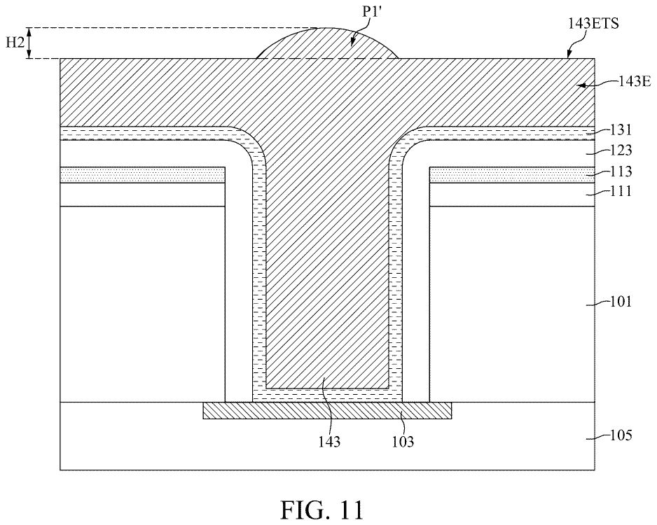

Subsequently, the conductive layer 143 is annealed, as shown in FIG. 11 in accordance with some embodiments. The respective step is illustrated as the step S25 in the method 10 shown in FIG. 1. In some embodiments, the protruding portion P1 of the conductive layer 143 overlapping the opening 120 (see FIG. 4) becomes an annealed protruding portion P1′. In some embodiments, the annealed protruding portion P1′ of the conductive layer 143 has a height H2, and the height H2 is greater than the height H1.

In some embodiments, the annealing is performed at a temperature of between about 350 °C and about 420 °C. In some embodiments, defects within the conductive layer 143 caused by the implantation process 140 are recovered through the annealing process. As a result, the conductive layer 143 can exhibit a substantially planar or slightly concave top surface after the subsequent planarization process(es).

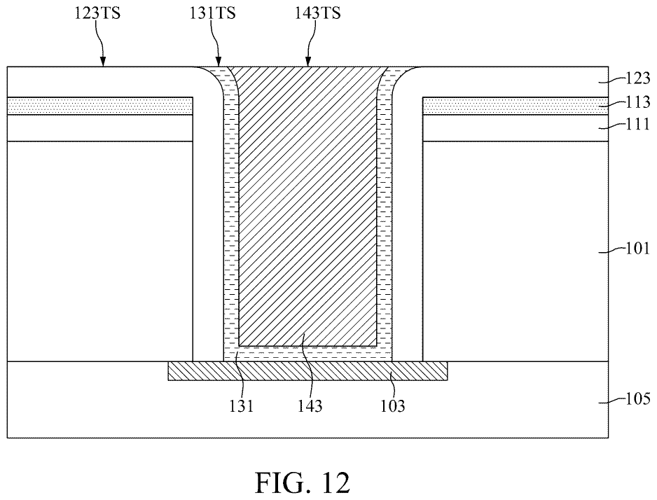

Then, a first planarization process is performed to expose the isolation layer 123, as shown in FIG. 12 in accordance with some embodiments. The respective step is illustrated as the step S27 in the method 10 shown in FIG. 1. In some embodiments, the first planarization process includes a chemical mechanical polishing (CMP) process. After the first planarization process is performed, the top surface 143TS of the conductive layer 143, the top surface 131TS of the barrier layer 131, and the top surface 123TS of the isolation layer 123 are substantially coplanar with each other, in accordance with some embodiments.

Next, a second planarization process is performed to expose the third dielectric layer 113, as shown in FIG. 13 in accordance with some embodiments. The respective step is illustrated as the step S29 in the method 10 shown in FIG. 1. In some embodiments, the second planarization process includes a CMP process. After the second planarization process is performed, the top surface 131TS′ of the remaining portion of the barrier layer 131, the top surface 123TS′ of the remaining portion of the isolation layer 123, and the top surface 113TS of the third dielectric layer 113 are substantially coplanar with each other, in accordance with some embodiments.

In the present embodiment, a recess 150 is formed over the conductive layer 143 after the second planarization process is performed, and the top surface 143TS′ of the remaining portion of the conductive layer 143 is slightly concave, while the top surface 131TS′ of the remaining portion of the barrier layer 131 is substantially planar. However, in some other embodiments, the remaining portion of the conductive layer 143 has a substantially planar top surface that is coplanar with the top surface 131TS′ of the remaining portion of the barrier layer 131 (i.e., the recess 150 does not exist).

In some embodiments, the recess 150 over the remaining portion of the conductive layer 143 has a height H3, and the remaining portion of the conductive layer 143 has a maximum height H4 close to the isolation layer 123. After the second planarization process is performed, a semiconductor device structure 100 includes a through-substrate via (TSV) 155 is obtained. In some embodiments, the TSV 155 includes the remaining portion of the barrier layer 131 and the remaining portion of the conductive layer 143.

Embodiments of a method for preparing the semiconductor device structure 100 are provided in the disclosure. The method includes forming the opening 120 penetrating through the semiconductor substrate 101, forming the barrier layer 131 lining the opening 120, and filling the remaining portion of the opening 120 with the conductive layer 143. The method also includes performing the implantation process 140 to implant a dopant (e.g., nitrogen (N)) into the conductive layer 143 during the forming of the conductive layer 143 (e.g., plating). The method further includes annealing the conductive layer 143 and planarizing the conductive layer 143 and the barrier layer 131 to form the TSV 155. As a result, the top surface 143TS′ of the conductive layer 143 of the TSV 155 is slightly concave or substantially planar while the top surface 131TS′ of the barrier layer 131 of the TSV 155 is substantially planar, thereby improving the overall performance of the semiconductor device structure 100.

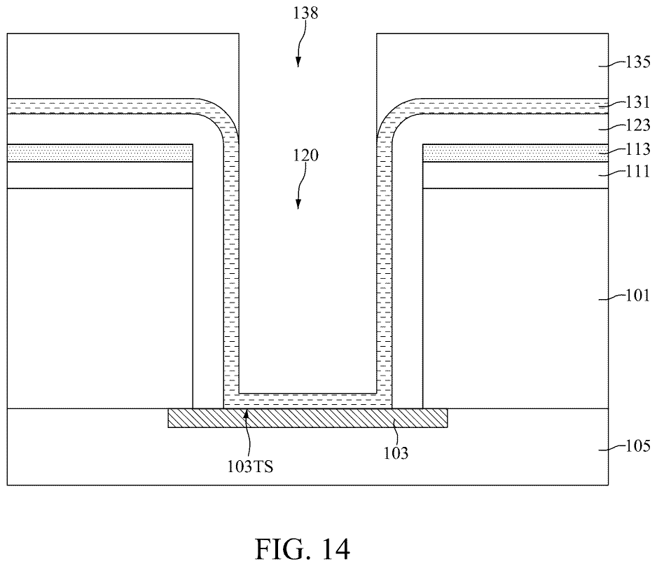

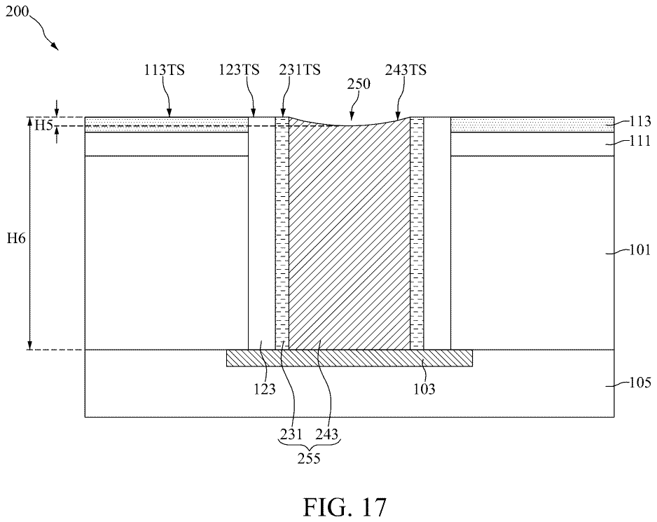

FIGS. 14-17 are cross-sectional views illustrating intermediate stages of another method for forming another semiconductor device structure 200 (FIG. 17), in accordance with some other embodiments. It should be pointed out that operations prior to the structure shown in FIG. 14 are substantially the same as those described in FIGS. 2-8. The related details may be referred to in the foregoing paragraphs and are not repeated herein.

After the barrier layer 131 is formed, a patterned mask 135 is formed over the barrier layer 131, as shown in FIG. 14 in accordance with some embodiments. In some embodiments, a portion of the barrier layer 131 that is in direct contact with the top surface 103TS of the conductive pad 103 is exposed by an opening 138 in the patterned mask 135. In some embodiments, the opening 138 overlaps the opening 120 (see FIG. 4). In some embodiments, the opening 138 is entirely located in the opening 120 from a top view.

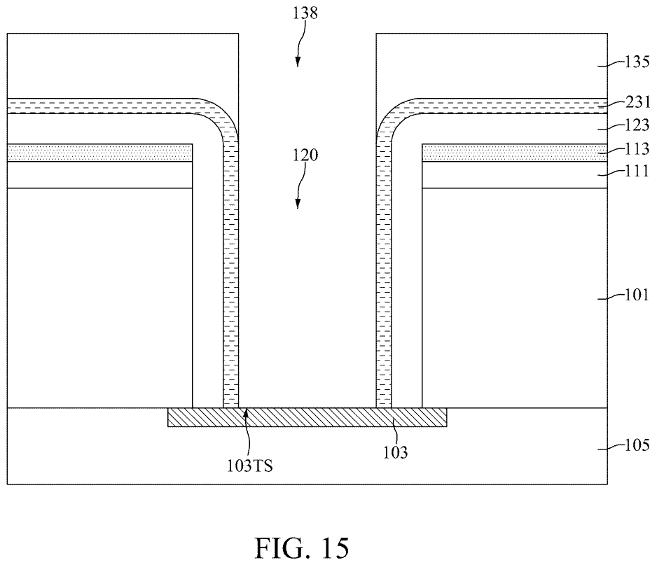

Next, the barrier layer 131 is etched using the patterned mask 135 as an etching mask to partially expose the conductive pad 103, as shown in FIG. 15 in accordance with some embodiments. In some embodiments, the top surface 103TS of the conductive pad 103 is partially exposed after the barrier layer 131 is etched. In some embodiments, the remaining portion of the barrier layer 131 is referred to as barrier layer 231.

In some embodiments, the barrier layer 131 is etched by a dry etching process, a wet etching process, or a combination thereof. After the top surface 103TS of the conductive pad 103 is partially exposed, the patterned mask 135 may be removed. In some embodiments, the patterned mask 135 is removed by a stripping process, an ashing process, an etching process, or another suitable process.

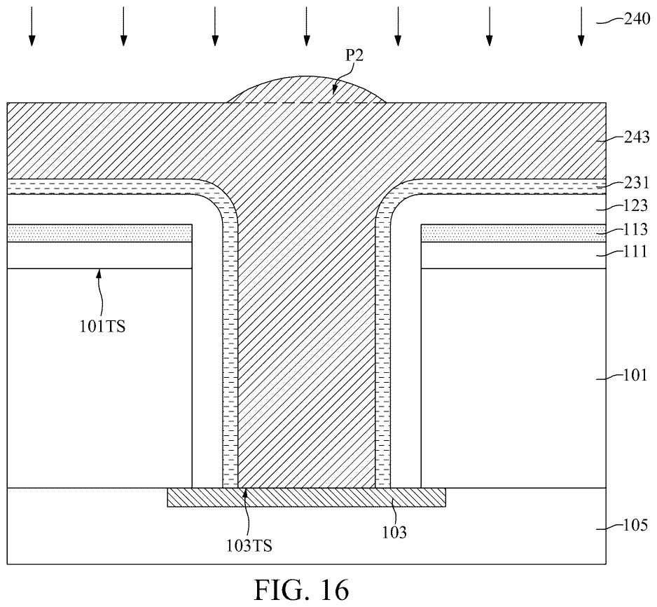

Subsequently, a conductive layer 243 is formed in the opening 120 and over the barrier layer 231, and an implantation process 240 is performed to implant a dopant into the conductive layer 243, as shown in FIG. 16 in accordance with some embodiments. In some embodiments, the implantation process 240 is performed during the forming of the conductive layer 243. In some embodiments, the implantation process 240 and the forming of the conductive layer 243 are performed simultaneously.

In some embodiments, after the barrier layer 231 is formed, a remaining portion of the opening 120 is filled with the conductive layer 243, and the conductive layer 243 extends over the top surface 101TS of the semiconductor substrate 101. In the present embodiment, the top surface 103TS of the conductive pad 103 is covered by and in direct contact with the conductive layer 243. In some embodiments, the conductive layer 243 has a protruding portion P2 overlapping the opening 120 (see FIG. 4). It is noted that the dashed line indicating the location of the protruding portion P2 is used to clarify the disclosure. No obvious interface exists within the conductive layer 243. Some details of the operations shown in FIG. 16 are similar to, or the same as those shown in FIG. 9 and are not repeated herein. For example, in some embodiments, the dopant used in the implantation process 240 includes nitrogen (N).

Then, an annealing process is performed on the structure of FIG. 16, and a first planarization process and a second planarization process are sequentially performed to expose the third dielectric layer 113, such that a semiconductor device structure 200 with a through-substrate via (TSV) 255 is obtained, as shown in FIG. 17 in accordance with some embodiments. In some embodiments, the TSV 255 includes the remaining portion of the barrier layer 231 and the remaining portion of the conductive layer 243. Some details of the annealing process are similar to, or the same as those described in FIG. 11, and are not repeated herein.

In some embodiments, the first planarization process and the second planarization process include CMP processes. Some details of the first and the second planarization processes performed between FIGS. 16 and 17 are similar to, or the same as those described in FIGS. 12 and 13, and are not repeated herein. After the first and the second planarization processes are performed, the top surface 231TS of the remaining portion of the barrier layer 231, the top surface 123TS of the remaining portion of the isolation layer 123, and the top surface 113TS of the third dielectric layer 113 are substantially coplanar with each other, in accordance with some embodiments.

In the present embodiment, a recess 250 is formed over the conductive layer 243 after the first planarization process and the second planarization process are performed, and the top surface 243TS of the remaining portion of the conductive layer 243 is slightly concave, while the top surface 231TS of the remaining portion of the barrier layer 231 is substantially planar. However, in some other embodiments, the remaining portion of the conductive layer 243 has a substantially planar top surface that is coplanar with the top surface 231TS of the remaining portion of the barrier layer 231 (i.e., the recess 250 does not exist).

In some embodiments, the recess 250 over the remaining portion of the conductive layer 243 has a height H5, and the remaining portion of the conductive layer 243 has a maximum height H6 close to the remaining portion of the barrier layer 231.

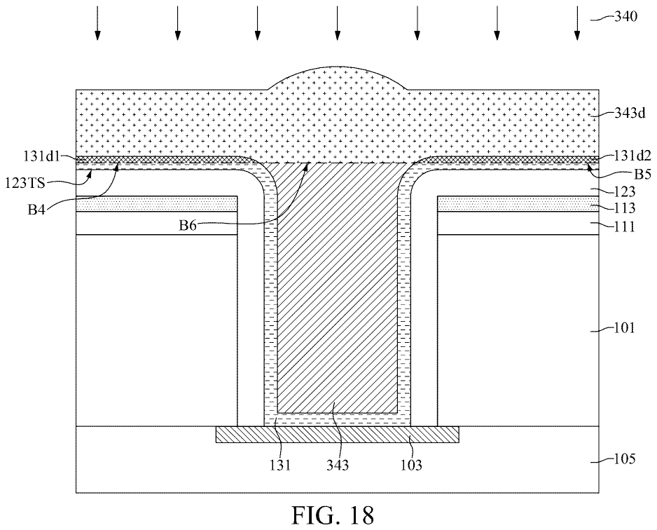

FIGS. 18-20 are cross-sectional views illustrating various dopant distributions after performing the implantation process during the preparation of the semiconductor device structure, in accordance with some other embodiments.

As shown in FIG. 18, a conductive layer 343 is formed, and an implantation process 340 is performed to implant a dopant into the conductive layer 343 during the formation of the conductive layer 343, in accordance with some embodiments. Some details of the conductive layer 343 and the implantation process 340 shown in FIG. 18 are similar to, or the same as, those of the conductive layer 143 and the implantation process 140 shown in FIG. 9, and are not repeated herein.

In some embodiments, after the conductive layer 343 is formed and the implantation process 340 is performed, a doped region 343d is formed in the conductive layer 343, and doped regions 131d1 and 131d2 are formed in the barrier layer 131. In some embodiments, the remaining portion of the conductive layer 343 and the remaining portion of the barrier layer 131 are undoped. Moreover, in the present embodiment, the bottom surface B4 of the doped region 131d1, the bottom surface B5 of the doped region 131d2, and the bottom surface B6 of the doped region 343d are higher than the top surface 123TS of the isolation layer 123. It is noted that the dashed line indicating the boundaries between the doped regions and the undoped regions are used to clarify the disclosure. No obvious interfaces exist between the doped regions and the undoped regions.

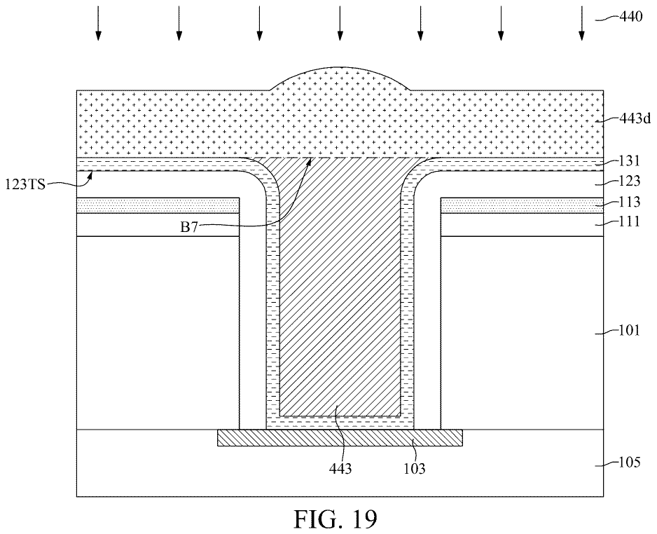

As shown in FIG. 19, a conductive layer 443 is formed, and an implantation process 440 is performed to implant a dopant into the conductive layer 443 during the formation of the conductive layer 443, in accordance with some embodiments. Some details of the conductive layer 443 and the implantation process 440 shown in FIG. 19 are similar to, or the same as, those of the conductive layer 143 and the implantation process 140 shown in FIG. 9, and are not repeated herein.

In some embodiments, after the conductive layer 443 is formed and the implantation process 440 is performed, a doped region 443d is formed in the conductive layer 443. In some embodiments, the barrier layer 131 and the remaining portion of the conductive layer 443 are undoped. Moreover, in the present embodiment, the bottom surface B7 of the doped region 443d is higher than the top surface 123TS of the isolation layer 123. It is noted that the dashed line indicating the boundaries between the doped regions and the undoped regions are used to clarify the disclosure. No obvious interfaces exist between the doped regions and the undoped regions.

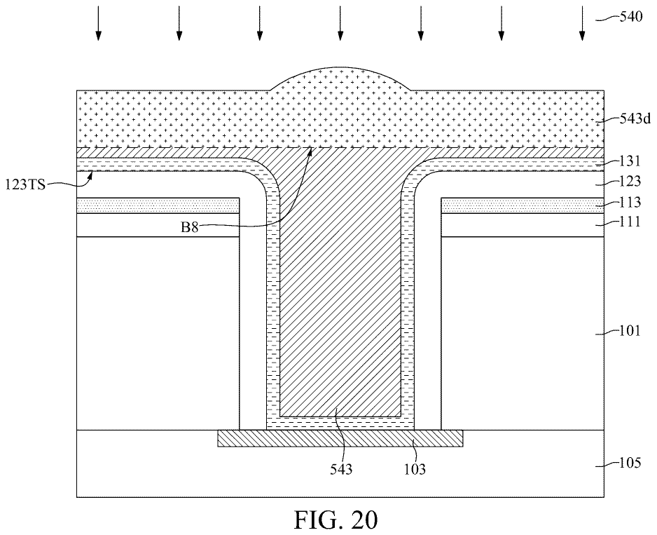

As shown in FIG. 20, a conductive layer 543 is formed, and an implantation process 540 is performed to implant a dopant into the conductive layer 543 during the formation of the conductive layer 543, in accordance with some embodiments. Some details of the conductive layer 543 and the implantation process 540 shown in FIG. 20 are similar to, or the same as, those of the conductive layer 143 and the implantation process 140 shown in FIG. 9, and are not repeated herein.

In some embodiments, after the conductive layer 543 is formed and the implantation process 540 is performed, a doped region 543d is formed in the conductive layer 543. In some embodiments, the barrier layer 131 and the remaining portion of the conductive layer 543 are undoped. Moreover, in the present embodiment, the bottom surface B8 of the doped region 543d is higher than the top surface 123TS of the isolation layer 123. It is noted that the dashed line indicating the boundaries between the doped regions and the undoped regions are used to clarify the disclosure. No obvious interfaces exist between the doped regions and the undoped regions.

Embodiments of a method for preparing a semiconductor device structure (e.g., the semiconductor device structure 100 or 200) with a through-substrate via (e.g., the through-substrate via 155 or 255) are provided in the disclosure. The method includes forming an opening (e.g., the opening 120) penetrating through a semiconductor substrate (e.g., the semiconductor substrate 101), forming a barrier layer (e.g., the barrier layer 131 or 231) lining the opening, and forming a conductive layer (e.g., the conductive layer 143 or 243) in the opening. The conductive layer is formed over the barrier layer and the semiconductor substrate. The method also includes implanting a dopant into the conductive layer during the forming of the conductive layer (e.g., the implantation process 140, 240, 340, 440 or 540). The method further includes annealing the conductive layer and planarizing the conductive layer and the barrier layer to form a TSV (e.g., the TSV 155 or 255.

In some embodiments, defects within the conductive layer caused by the implantation process are recovered through the annealing process. Therefore, the conductive layer can exhibit a substantially planar or slightly concave top surface after the subsequent planarization process(es). For example, the top surface 143TS′ of the conductive layer 143 and the top surface 243TS of the conductive layer 243 are slightly concave while the top surface 131TS′ of the barrier layer 131 and the top surface 231TS of the barrier layer 231 are substantially planar. As a result, the overall performance of the semiconductor device structure can be improved. In addition, since the implantation process is performed during the formation of the conductive layer, the process cost can be reduced.

In one embodiment of the present disclosure, a method for preparing a semiconductor device structure is provided. The method includes forming an opening penetrating through a semiconductor substrate, and forming a barrier layer lining the opening. The method also includes forming a conductive layer in the opening and over the barrier layer and the semiconductor substrate. The method further includes implanting a dopant into the conductive layer during the forming of the conductive layer. In addition, the method includes annealing the conductive layer after the implanting the dopant, and planarizing the conductive layer and the barrier layer after the annealing.

In another embodiment of the present disclosure, a method for preparing a semiconductor device structure is provided. The method includes forming an opening penetrating through a semiconductor substrate, and forming a barrier layer lining the opening and over a top surface of the semiconductor substrate. The method also includes forming a conductive layer in the opening and simultaneously implanting a dopant in the conductive layer. The method further includes annealing the conductive layer. In addition, the method includes planarizing the conductive layer and the barrier layer after the annealing. A top surface of the conductive layer is slightly concave while a top surface of the barrier layer is substantially planar after the planarizing.

In yet another embodiment of the present disclosure, a method for preparing a semiconductor device structure is provided. The method includes forming a conductive pad over a first side of a semiconductor substrate, and forming a dielectric layer over a second side of the semiconductor substrate. The second side is opposite to the first side. The method also includes etching the dielectric layer and the semiconductor substrate to form an opening partially exposing the conductive pad, and forming an isolation layer lining the opening and over the dielectric layer. The method further includes forming a barrier layer lining the opening and over the isolation layer, and forming a conductive layer in the opening and implanting a dopant into the conductive layer during the forming of the conductive layer. The barrier layer is sandwiched between the conductive layer and the isolation layer. In addition, the method includes annealing the conductive layer after the implanting, and planarizing the conductive layer and the barrier layer after the annealing.

The embodiments of the present disclosure have several advantageous features. By implanting a dopant into the conductive layer during its formation, a slightly concave or substantially planar top surface of the conductive layer can be achieved. As a result, the overall performance of the semiconductor device structure can be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A method for preparing a semiconductor device structure, comprising:
forming an opening penetrating through a semiconductor substrate;
forming a barrier layer lining the opening and over a top surface of the semiconductor substrate;
forming a conductive layer in the opening and simultaneously implanting a dopant in the conductive layer;
annealing the conductive layer; and
planarizing the conductive layer and the barrier layer after the annealing, wherein a top surface of the conductive layer is slightly concave while a top surface of the barrier layer is substantially planar after the planarizing.

2. The method for preparing a semiconductor device structure of claim 1, wherein the dopant comprises nitrogen (N).

3. The method for preparing a semiconductor device structure of claim 2, wherein the conductive layer comprises copper (Cu), and the barrier layer comprises tantalum (Ta).

4. The method for preparing a semiconductor device structure of claim 1, wherein the implanting is performed at an energy of between about 1 KeV and about 3 KeV.

5. The method for preparing a semiconductor device structure of claim 4, wherein the implanting uses an implantation dosage between about 3×10⁶ atoms/cm³ and about 6×10⁶ atoms/cm³.

6. The method for preparing a semiconductor device structure of claim 1, wherein the conductive layer has a protruding portion overlapping the opening before the annealing is performed.

7. The method for preparing a semiconductor device structure of claim 6, wherein the conductive layer has an extending portion extending over the top surface of the semiconductor substrate, and the protruding portion of the conductive layer protrudes from a top surface of the extending portion of the conductive layer.

8. The method for preparing a semiconductor device structure of claim 7, wherein the protruding portion of the conductive layer has a first height over the top surface of the extending portion of the conductive layer before the annealing, and the protruding portion of the conductive layer has a second height over the top surface of the extending portion of the conductive layer after the annealing, and wherein the second height is greater than the first height.

9. The method for preparing a semiconductor device structure of claim 7, wherein the dopant is implanted into the protruding portion and the extending portion of the conductive layer.

10. The method for preparing a semiconductor device structure of claim 9, wherein the dopant is implanted into the barrier layer.

11. The method for preparing a semiconductor device structure of claim 1, further comprising:
forming a dielectric layer over the semiconductor substrate before the opening is formed;
forming the opening penetrating through the semiconductor substrate and the dielectric layer; and
forming an isolation layer lining the opening and over the dielectric layer before the barrier layer is formed.

12. The method for preparing a semiconductor device structure of claim 1, wherein the planarizing the conductive layer and the barrier layer further comprises:
performing a first planarization process to expose the isolation layer; and
performing a second planarization process to expose the dielectric layer.

13. The method for preparing a semiconductor device structure of claim 12, wherein the conductive layer and the barrier layer have substantially coplanar top surfaces after the first planarization process and before the second planarization process.
